(19) United States
(12) Patent Application Publication
(10) Pub. No.: US 2026/0140307 A1
(43) Pub. Date: May 21, 2026

(54) CO-PACKAGED OPTICS STRUCTURE WITH SUBSTRATE-EMBEDDED OPTICAL INTERCONNECTS

(71) Applicant: International Business Machines Corporation, Armonk, NY (US)

(72) Inventors: John Lucas Darling, Ballston Spa, NY (US); Qianwen Chen, Fort Collins, CO (US); Hsianghan Hsu, Latham, NY (US); Neng Liu, Albany, NY (US); John Knickerbocker, Monroe, NY (US)

(21) Appl. No.: 18/952,314

(22) Filed: Nov. 19, 2024

(51) Int. Cl. G02B 6/122; G02B 6/12; H01L 23/14; H01L 23/538; H01L 25/16

(52) U.S. Cl. CPC G02B 6/122; H10W 70/611; H10W 70/635; H10W 90/00; G02B 2006/12038; G02B 2006/12061; H10W 70/698

(57) ABSTRACT

A semiconductor structure includes a substrate, one or more electrical interconnects disposed in through-substrate vias extending vertically from an upper surface of the substrate to a lower surface of the substrate, one or more optical interconnects embedded in the substrate between the upper surface of the substrate and the lower surface of the substrate, and one or more optical connector pin holes extending from at least one side of the substrate between the upper surface of the substrate and the lower surface of the substrate.

### BACKGROUND

The present application relates to packaging techniques for photonics applications, and more specifically, to techniques for integrating photonic devices with electrical components in co-packaged optics (CPO).

Photonics devices and applications are configured for performing various functions that involve light. Such functions include, but are not limited to, generating, emitting, transmitting, modulating, signal processing, amplifying and detecting or sensing light within visible and near-infrared portions of the electromagnetic spectrum. CPO techniques may be leveraged for implementing photonics applications. CPO techniques, for example, include co-fabricating optoelectronic devices or photonic devices with complementary metal-oxide-semiconductor (CMOS) integrated circuits to implement photonics systems. Photonics applications, however, may also be fabricated without integrated CMOS circuitry, though the lack of integrated CMOS circuitry does not provide CMOS functions and thus lack analog and digital on-chip controls.

Computer system performance may be measured by system availability, speed of computation, processor speed, etc. Communication or network bandwidth between computers and between components within a computer can also contribute to a computer system's overall performance. Computer systems may include multi-core processors and multiple processors per machine, including combination of central processing units (CPUs) and one or more graphical processing units (GPUs), requiring an increase in communication therebetween and between such processor units their associated memory. Electrical data links perform best over relatively short distances, and reach performance limits as the link distance and frequency increases. Optical data links over fiber are capable of high-speed communications with low loss over larger distances than electrical data links. Co-packaged optics solutions may be leveraged to obtain such benefits in combination with the use of electrical components in integrated circuits.

### SUMMARY

Embodiments of the invention provide techniques for forming co-packaged optics structures with substrate-embedded optical interconnects.

In one embodiment, a semiconductor structure includes a substrate, one or more electrical interconnects disposed in through-substrate vias extending vertically from an upper surface of the substrate to a lower surface of the substrate, one or more optical interconnects embedded in the substrate between the upper surface of the substrate and the lower surface of the substrate, and one or more optical connector pin holes extending from at least one side of the substrate between the upper surface of the substrate and the lower surface of the substrate.

In another embodiment, a co-packaged optics structure includes a substrate having one or more electrical interconnects and one or more optical interconnects, the one or more electrical interconnects extending vertically between upper and lower surfaces of the substrate, the one or more optical interconnects being embedded in the substrate between the upper and lower surfaces of the substrate, wherein at least a subset of the one or more optical interconnects extend from (i) at least one side of the substrate between the upper and lower surfaces of the substrate to (ii) a first portion of the upper surface of the substrate. The co-packaged optics structure also includes at least one photonic die coupled to the first portion of the upper surface of the substrate, and at least one electrical die coupled to a second portion of the upper surface of the substrate.

In another embodiment, a photonics system includes a first co-packaged optics structure, the first co-packaged optics structure including a first substrate with a first set of optical interconnects embedded between upper and lower surfaces of the first substrate, and a second co-packaged optics structure, the second co-packaged optics structure including a second substrate with a second set of optical interconnects embedded between upper and lower surfaces of the second substrate. At least a first subset of the first set of optical interconnects of the first co-packaged optics structure are coupled with at least a second subset of the second set of optical interconnects of the second co-packaged optics structure.

### BRIEF DESCRIPTION OF THE DRAWINGS

FIG. 1 shows a co-packaged optics structure with optical interconnects embedded in a substrate thereof, according to an embodiment of the invention.

FIGS. 2A-2G show a process flow for forming a co-packaged optics structure with optical interconnects embedded in a substrate, according to an embodiment of the invention.

FIGS. 3A-3C show views of a co-packaged optics module with substrate-embedded optical interconnects, according to an embodiment of the invention.

FIG. 4 shows an optical connector configured for coupling with a co-packaged optics module with substrate-embedded optical interconnects, according to an embodiment of the invention.

FIG. 5 shows a unidirectional series connection of co-packaged optics modules with substrate-embedded optical interconnects, according to an embodiment of the invention.

FIG. 6 shows a bidirectional series connection of co-packaged optics modules with substrate-embedded optical interconnects, according to an embodiment of the invention.

FIG. 7 shows a photonics system having multiple co-packaged optics modules with substrate-embedded optical interconnects, according to an embodiment of the invention.

FIG. 8 shows an integrated circuit comprising one or more co-packaged optics structures with substrate-embedded optical interconnects, according to an embodiment of the invention.

### DETAILED DESCRIPTION

Illustrative embodiments of the invention may be described herein in the context of illustrative methods for forming co-packaged optics structures with substrate-embedded optical interconnects, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

As discussed above, co-packaged optics (CPO) techniques may be leveraged for implementing photonics applications, where a CPO structure is formed by co-fabricating optoelectronic or photonic devices together with complementary metal-oxide-semiconductor (CMOS) or other semiconductor integrated circuits to provide photonics systems. Substrates used for CPO should have robust mechanical properties, as the alignment tolerance is tight for optical components. In conventional approaches, optical waveguides and couplers are typically formed on the surface of an organic substrate to produce CPO structures. Glass core substrates provide various benefits, including a tunable modulus and coefficient of thermal expansion (CTE) to silicon, higher temperature stability, low optical loss, etc. Optically, glass can act as both a core and cladding material for optical interconnects (e.g., optical waveguides) under different configurations.

Illustrative embodiments provide techniques for forming optical waveguides and alignment couplers which are embedded into glass or silicon interposers or other substrates, or integrated hybrid interposer and base packages. By embedding optical waveguides or other optical interconnects in the interposer or substrate, “through-substrate” or “substrate-embedded” optical interconnects are provided in CPO structures, with optical and electrical input/output (I/O) and physical links on and/or off the CPO structures. In some embodiments, methods are provided for integrating optical interconnects (e.g., optical waveguides and couplers) in a glass or silicon substrate, with through-glass vias (TGVs) and/or through-silicon vias (TSVs) being used for electrical and optical CPO applications. TGVs and TSVs are examples of what are more generally referred to herein as through-substrate vias.

In some embodiments, a semiconductor structure includes a glass, silicon or hybrid glass/silicon substrate, interposer or package with optical interconnects embedded in and through the substrate. The optical interconnects may include one or more horizontal layers of optical interconnects, one or more vertical vias, straight, curved and/or tapered optical waveguides (e.g., glass optical waveguide (GOW) arrays, etc.), etc. The substrate, which may be glass, silicon or a hybrid package, may further include optical connector-compatible pin holes (e.g., for connecting Multi-fiber Push On (MPO) connectors to the CPO structures). The substrate may also include horizontal and/or vertical electrical interconnects for interconnecting components on the top (front side) and bottom (back side) surfaces of the substrate. Vertical electrical interconnects may be formed with TGVs, TSVs, organic connections, etc. There may be a single or multiple electronic component assemblies which are on the top of or embedded in the substrate. Further, a single or multiple photonic dies and/or electrical die assemblies may be on the top of or embedded in the substrate.

Locating optical interconnects inside a substrate provides various technical benefits. Embedded or through-substrate optical interconnects can advantageously utilize the thickness of the substrate to make optical connector-compatible mechanisms (e.g., MPO connector compatible mechanisms), which provides benefits in reduction of coupling loss from optical fibers to the substrate. Further, the embedded optical interconnects (e.g., GOWs) are protected by the substrate, which increases their mechanical robustness. In addition, the use of embedded optical interconnects enables more flexibly photonic wiring which does not interfere with surface configurations such as molding processes and lid attachment. Further, substrate-embedded optical interconnects enable optical communication between dies on the same or different substates (e.g., multiple CPO modules) which can be implemented with unidirectional and bidirectional scaling. The substrate-embedded optical interconnects also advantageously free up surface area in the substrate for forming horizontal and vertical electrical interconnects.

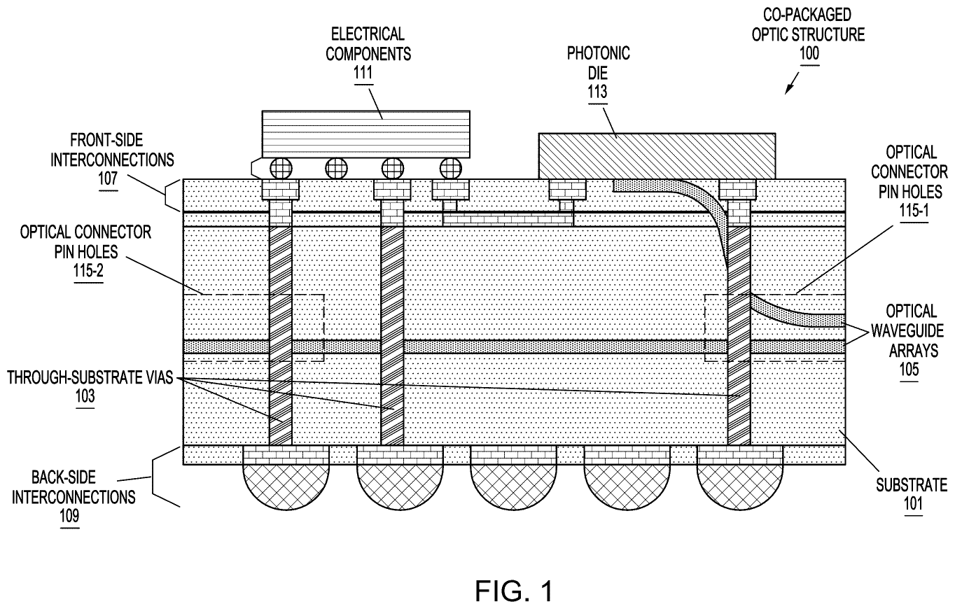

FIG. 1 shows a CPO structure 100 which includes substrate-embedded optical interconnects. The CPO structure 100 includes a substrate 101, which may be a glass or silicon interposer or other substrate, a hybrid glass/silicon substrate, etc. A set of through-substrate vias 103 are formed vertically through the substrate 101. Optical waveguide arrays 105 are also formed or embedded in the substrate 101. The optical waveguide arrays 105 are examples of what are more generally referred to herein as optical interconnects. The optical waveguide arrays 105 include a “straight” optical waveguide array that extends horizontally across the substrate 101 as well as a “tapered” optical waveguide array that extends from a vertical position between upper and lower surfaces at one side of the substrate 101, and which taper or extend to the upper (i.e., the top or front side) of the substrate 101 as illustrated.

A set of front-side interconnections 107 are formed on the upper (i.e., the top or front side) of the substrate 101, and a set of back-side interconnections are formed on the lower (e.g., the bottom or back side) of the substrate 101. The front-side interconnections 107 may include interconnects and vias in one or more multiple levels, which facilitate interconnection with electrical components 111 and a photonic die 113, and connections between the electrical components 111 and the photonic die 113. The back-side interconnections 109 may include a ball grid array (BGA) or land grid array (LGA) for surface-mounting of the CPO structure 100 to other circuitry. The through-substrate vias 103 enable connections between the front-side interconnections 107 and the back-side interconnects 109. The CPO structure 100 further includes optical connector pin holes 115-1 and 115-2 (collectively, optical connector pin holes 115). The optical connector pin holes 115 enable coupling of the CPO structure 100 with optical connectors (e.g., MPO connectors) or other CPO structures (e.g., in unidirectional or bidirectional series connection).

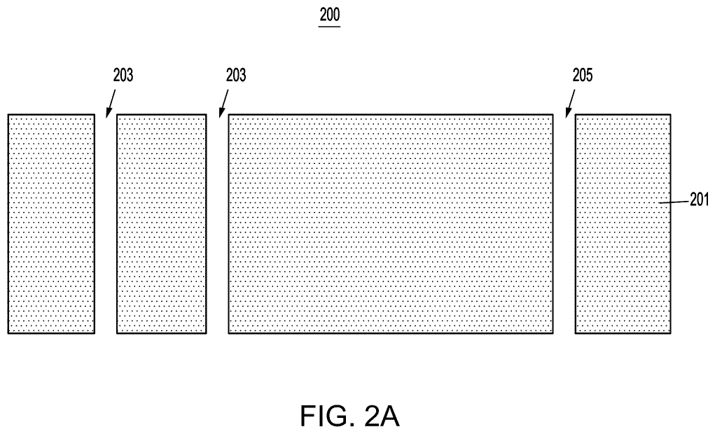

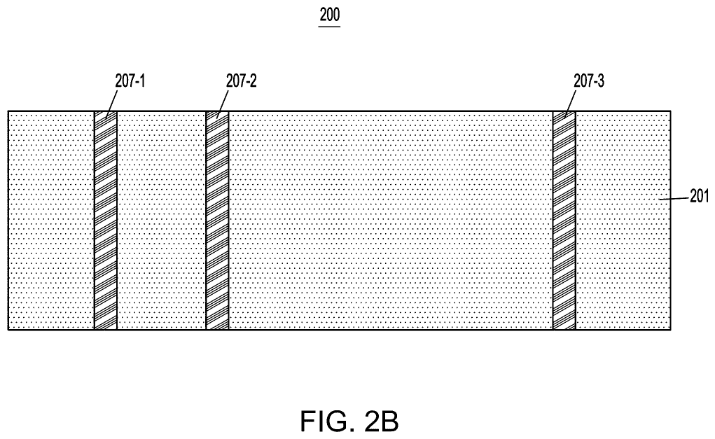

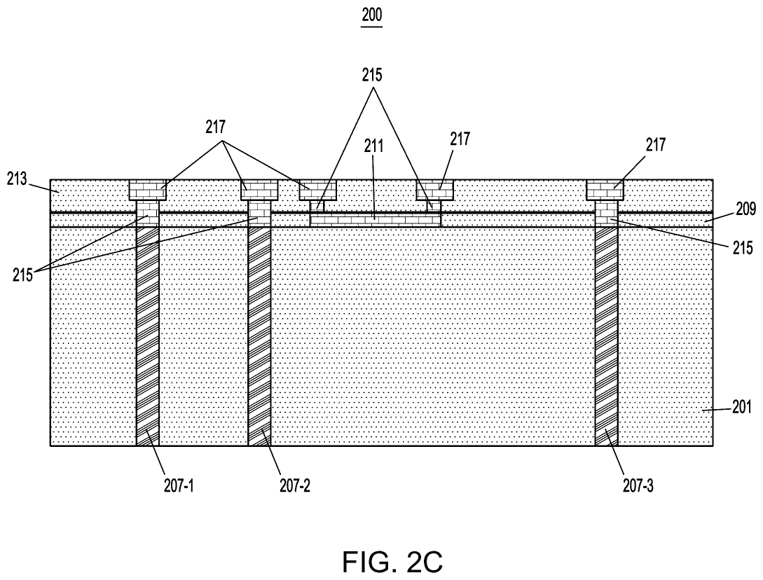

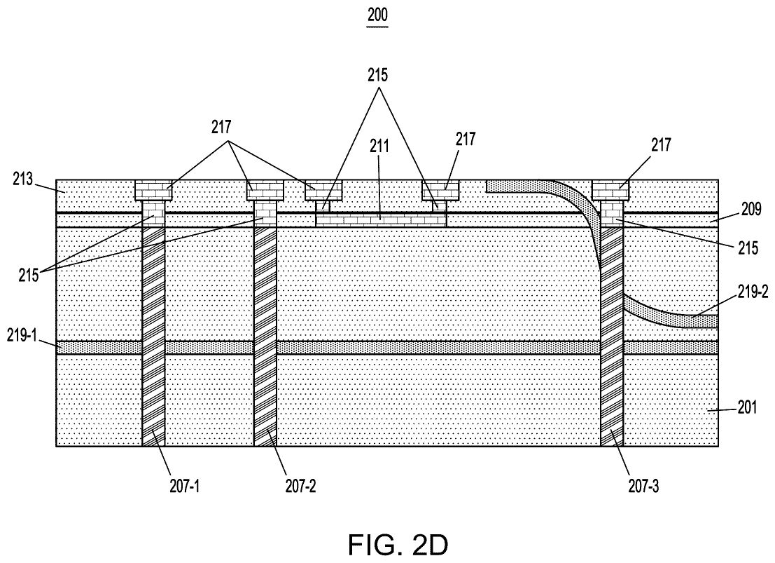

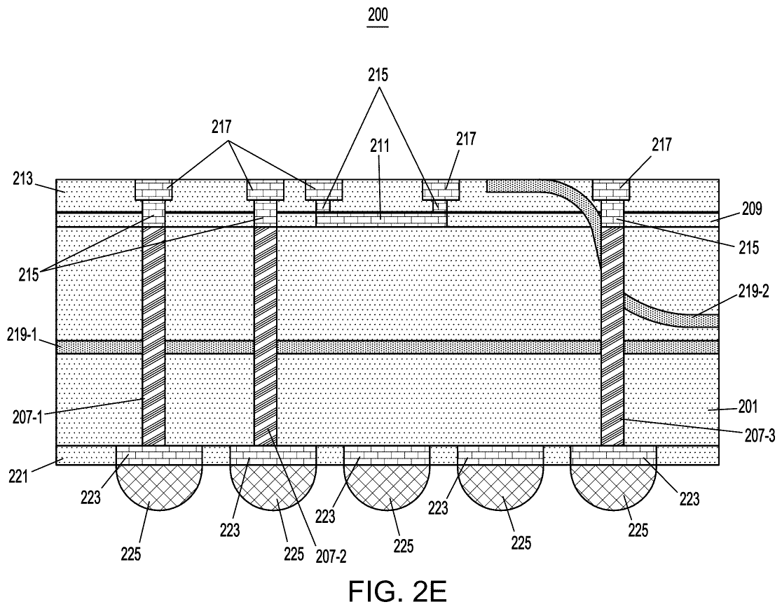

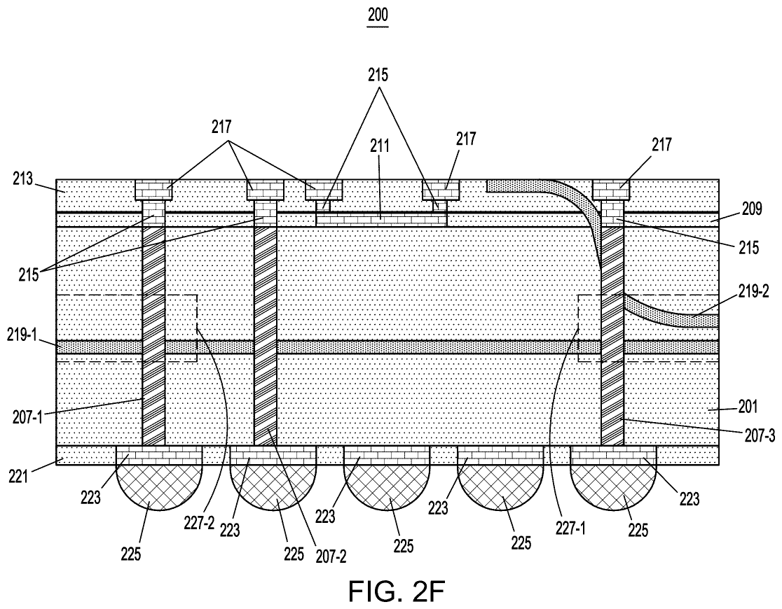

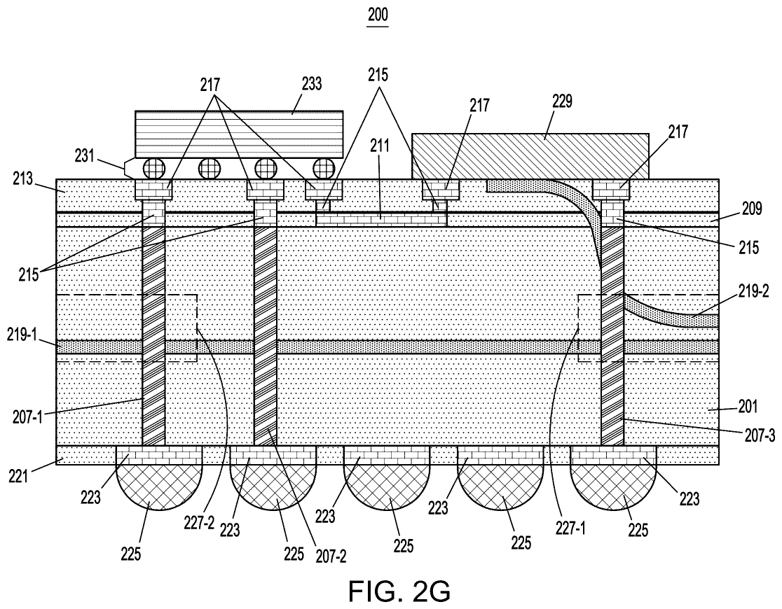

FIGS. 2A-2G show a process flow for fabricating a CPO structure (e.g., the CPO structure 100 shown in FIG. 1). FIG. 2A shows a cross-sectional view of a semiconductor structure 200 including a substrate 201 with vias 203 and 205 formed therein. The substrate 201 may be a glass substrate, with the vias 203 and 205 being laser drilled through the glass.

FIG. 2B shows a cross-sectional view of the semiconductor structure 200 of FIG. 2A following formation of through-substrate vias 207-1, 207-2 and 207-3 (collectively, through-substrate vias 207). Where the substrate 201 is a glass substrate, the through-substrate vias 207 are TGVs, which may be fabricated through deposition of a liner and/or seed layer, followed by copper electroplating and chemical mechanical planarization (CMP) processes.

FIG. 2C shows a cross-sectional view of the semiconductor structure 200 of FIG. 2B following formation of front-side electrical interconnects. This includes formation of an additional substrate 209, and formation of an interconnect 211 in the substrate 209 (e.g., through patterning of a mask layer, etching through the substrate 209, and fill and planarization of a suitable interconnect material, which may but is not required to be the same material filled in the through-substrate vias 207). An additional substrate 213 is then formed, followed by formation of vias 215 therein (e.g., through patterning of a mask layer, etching through the substrate 213, and fill and planarization of a suitable via material, which may but is not required to be the same material filled in the through-substrate vias 207 and/or the material used for the interconnect 211). Interconnects 217 are then formed in the substrate 213 to connect to the underlying vias 215. The interconnects 217 may be formed through patterning of a mask layer, etching through a portion of the substrate 213, and fill and planarization of a suitable interconnect material, which may but is not required to be the same material filled in the through-substrate vias 207 and/or the material used for the interconnect 211 and the vias 215.

FIG. 2D shows a cross-sectional view of the semiconductor structure 200 of FIG. 2C following formation of optical interconnects 219-1 and 219-2 (collectively, optical interconnects 219). The optical interconnects 219 may be GOW arrays, where the optical interconnects 219-1 provide a “straight” GOW array which extends horizontally across the substrate 201, while the optical interconnects 219-2 provide a “tapered” GOW array which extends from a side of the substrate 201 to an upper (i.e., top or front side) surface of the substrate 201. The optical interconnects 219 may be formed using laser direct write technology.

FIG. 2E shows a cross-sectional view of the semiconductor structure 200 of FIG. 2D following formation of backside interconnects. This includes forming an additional substrate 221 on the lower (i.e., bottom or back side) surface of the substrate 201, formation of interconnects 223 (e.g., through patterning of a mask layer, etching through the substrate 221, and fill and planarization of a suitable interconnect material, which may but is not required to be the same material filled in the through-substrate vias 207 and/or the material used for the interconnect 211, the vias 215 and/or the interconnects 217). Solder bumps 225 are then formed to contact the interconnects 223. Although not explicitly shown, the semiconductor structure 200 may be part of a larger overall structure that is diced to former individual dies for CPO structures or modules.

FIG. 2F shows a cross-sectional view of the semiconductor structure 200 of FIG. 2E following formation of optical connector pin holes 227-1 and 227-2 (collectively, optical connector pin holes 227). The optical connector pin holes 227 may be formed by laser drilling into the substrate 201 to make precise optical connector (e.g., MPO) compatible pin holes. It should be noted that while FIG. 2F shows an example where a first set of optical connector pin holes 227-1 are formed at a first side of the substrate 201 and a second set of optical connector pin holes 227-2 are formed at a second side of the substrate 201, this is not a requirement. In some embodiments, the optical connector pin holes 227-2 may be omitted. Further, depending on the configuration of optical interconnects embedded in a substrate, additional optical connector pin holes may be formed on additional sides of the substrate, or at different locations between upper and lower surfaces of the substrate at one or more sides of the substrate.

FIG. 2G shows a cross-sectional view of the semiconductor structure 200 of FIG. 2F following bonding of a photonic die 229 to the upper surface of the substrate 201 (e.g., so as to be positioned for connection or coupling with the tapered optical interconnections 219-2 as well as the interconnects 217 which connects, through vias 215, to the through-substrate via 207-2 and the interconnect 211. Solder bumps 231 are used to bond an electrical die 233 (e.g., electrical components) to the upper surface of the substrate 201. More specifically, the solder bumps 231 connect the electrical die 233 with ones of the interconnects 217 which connect, through vias 215, to the through-substrate vias 207-1 and 207-2 as well as the interconnect 211. As illustrated, the interconnect 211 facilitates electrical interconnection between the photonic die 229 and the electrical die 233 (e.g., through different ones of the vias 215 and interconnects 217 at the front side of the substrate 201). In some embodiments, the photonic die 229 is joined to the substrate 201 with a hybrid bonding method.

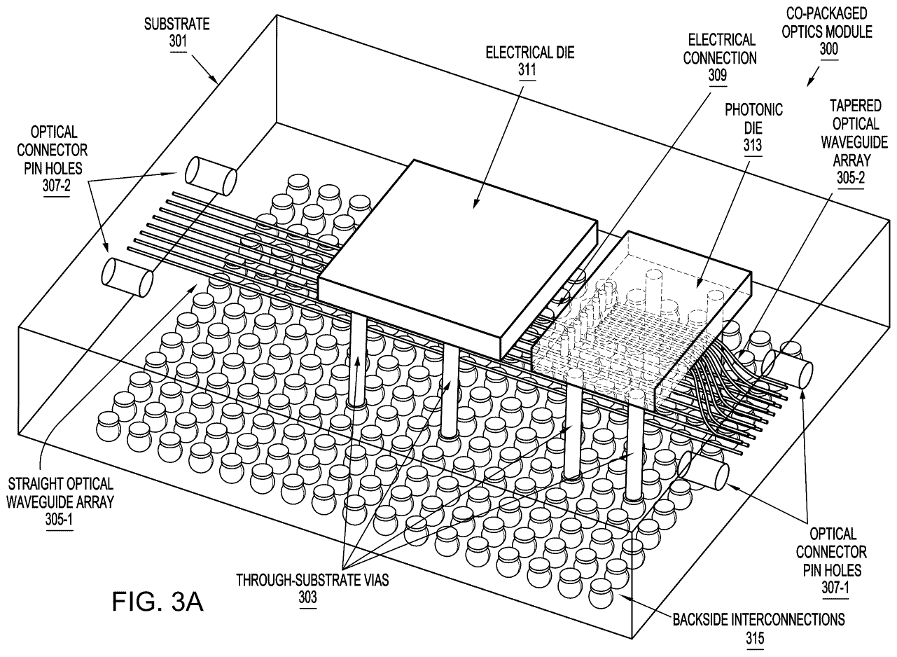

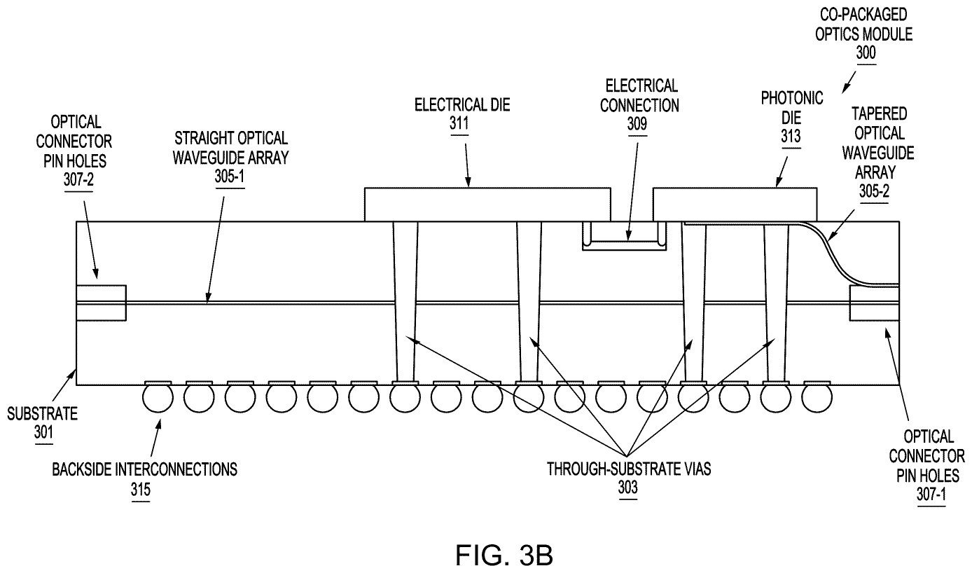

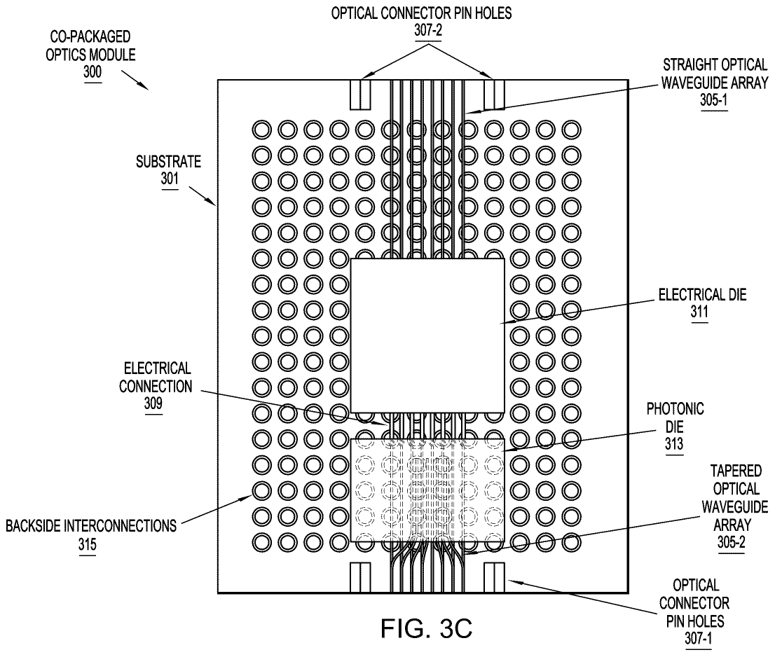

FIGS. 3A-3C show views of a CPO module 300. FIG. 3A shows a perspective view of the CPO module 300, while FIG. 3B shows a side cross-sectional view of the CPO module 300 and FIG. 3C shows a top-down view of the CPO module 300. The CPO module 300 includes a substrate 301, through-substrate vias 303, a straight optical waveguide array 305-1 and a tapered optical waveguide array 305-2 (collectively, optical waveguide arrays 305), optical connector pin holes 307-1 and 307-2 (collectively, optical connector pin holes 307), an electrical connection 309 interconnecting electrical die 311 and photonic die 313 attached to an upper (e.g., top or front side) of the substrate 301, and backside interconnections 315.

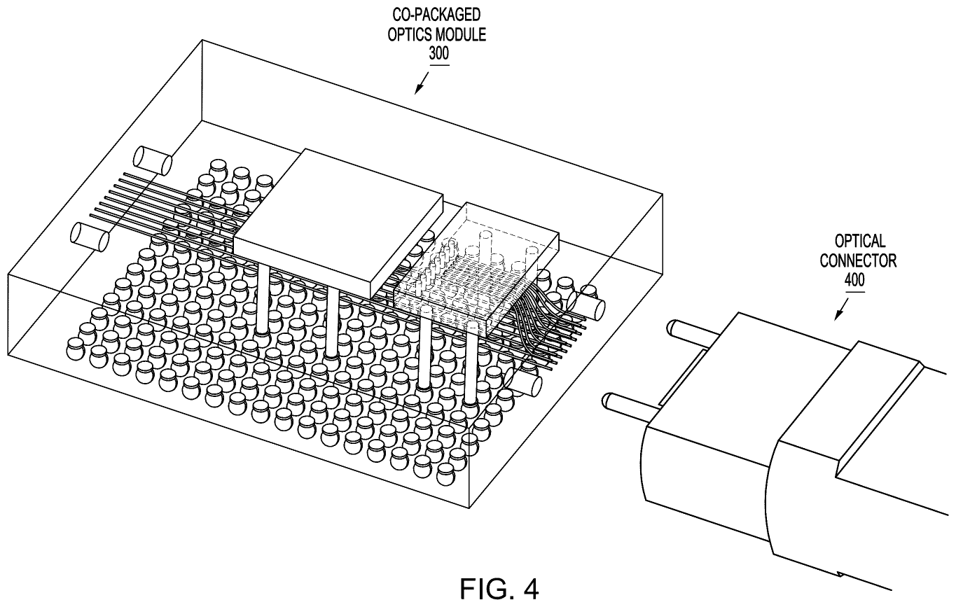

FIG. 4 shows a perspective view of the CPO module 300 and an optical connector 400 (e.g., an MPO connector) configured for attachment or coupling to the optical connector pin holes 307-1.

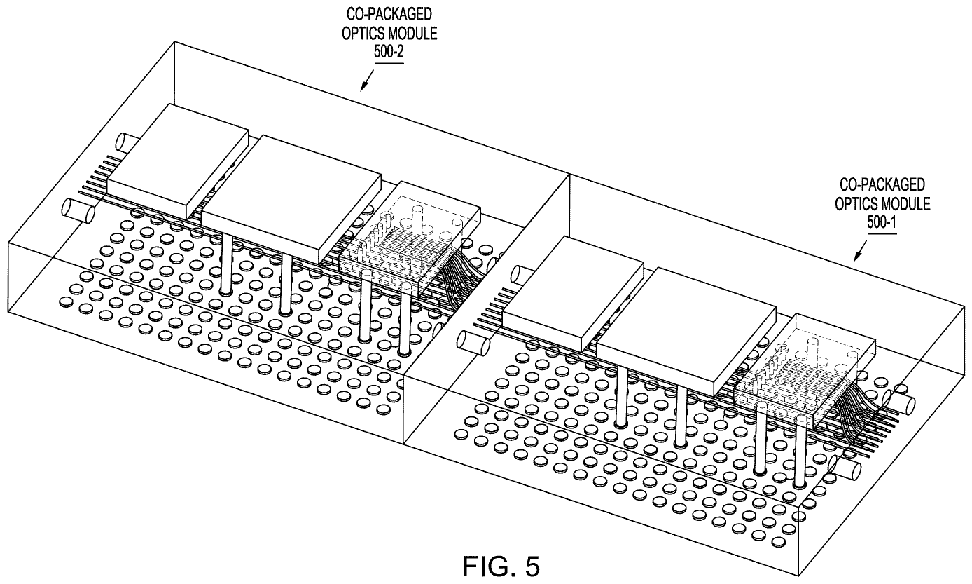

FIG. 5 shows a perspective view of two CPO modules 500-1 and 500-2 (collectively, CPO modules 500) connected unidirectionally in series. Here, each of the CPO modules 500-1 and 500-2 are similar in configuration to the CPO module 300.

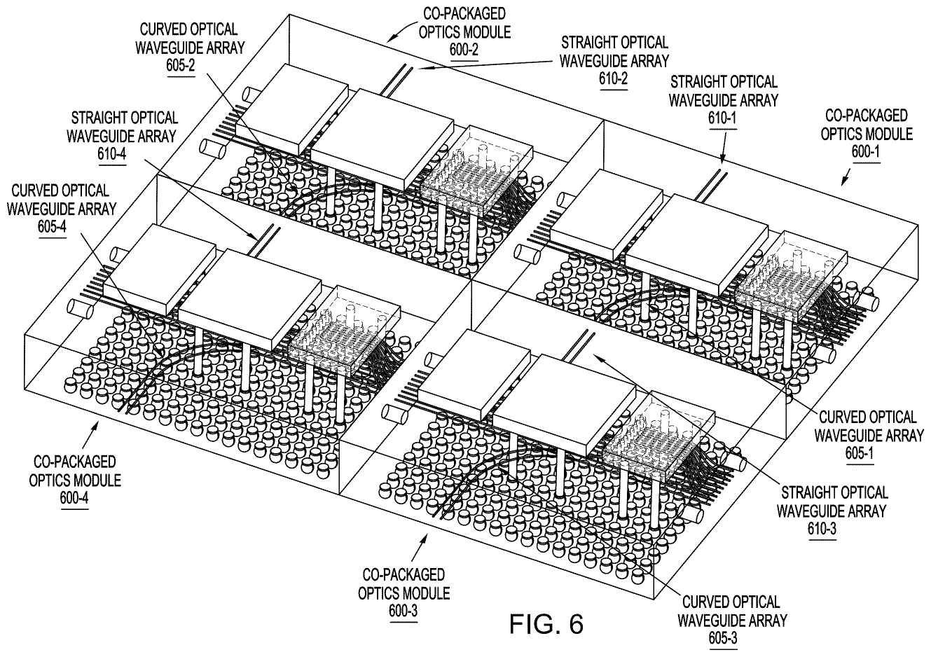

FIG. 6 shows a perspective view of four CPO modules 600-1, 600-2, 600-3 and 600-4 (collectively, CPO modules 600) connected bidirectionally in series. Here, each of the CPO modules 600-1, 600-2, 600-3 and 600-4 includes, relative to the CPO module 300 shown in FIGS. 3A-3C, respective additional curved optical waveguide arrays 605-1, 605-2, 605-3 and 605-4 (collectively, curved optical waveguide arrays 605) and additional straight optical waveguide arrays 610-1, 610-2, 610-3 and 610-4 (collectively, straight optical waveguide arrays 610). The straight optical waveguide arrays 610 are arranged orthogonal to the straight optical waveguide array 305-1. The curved optical waveguide arrays 605, instead of tapering or bending to connect a side and upper surfaces of the substrate, extend from one side to another side of the substrate between the upper and lower surfaces thereof as illustrated. The curved optical waveguide arrays 605 and the straight optical waveguide arrays 610 facilitate the bidirectional series connection of the CPO modules 600. For example, the curved optical waveguide array 605-1 of the CPO module 600-1 is arranged to connect with the straight optical waveguide array 610-3 of the CPO module 600-3, and the curved optical waveguide array 605-2 of the CPO module 600-2 is arranged to connect with the straight optical waveguide array 610-4 of the CPO module 600-4.

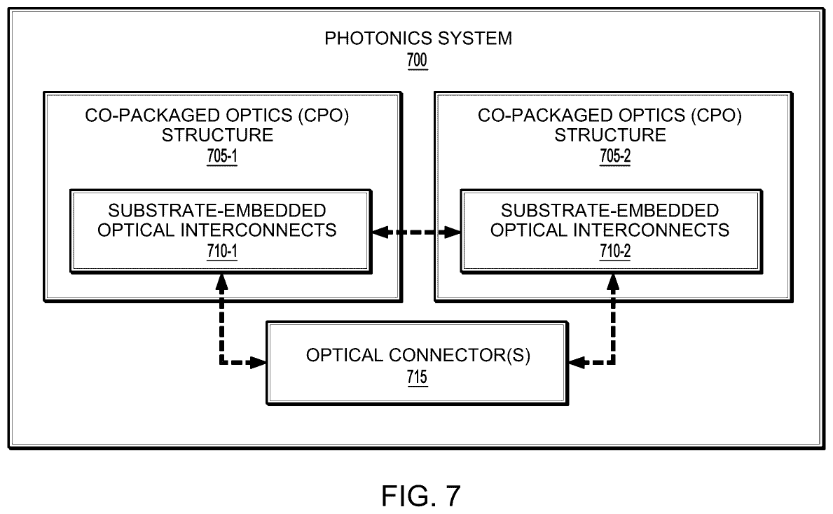

FIG. 7 shows a photonics system 700 which includes co-packaged optics structures 705-1 and 705-2 (collectively, co-packaged optics structures 705) having substrate-embedded optical interconnects 710-1 and 710-2 (collectively, substrate-embedded optical interconnects 710). The substrate-embedded optical interconnects 710-1 of the co-packaged optics structure 705-1 are configured for coupling with the substrate-embedded optical interconnects 710-2 of the co-packaged optics structure 705-2. The photonics system 700 further includes one or more optical connectors 715 configured for coupling with at least one of the substrate-embedded optical interconnects 710-1 of the co-packaged optics structure 705-1 and the substrate-embedded optical interconnects 710-2 of the co-packaged optics structure 705-2. The co-packaged optics structures 705 may be configured in a manner similar to that of the co-packaged optics module 300, the co-packaged optics modules 500 or the co-packaged optics modules 600.

According to an aspect of the invention, a semiconductor structure includes a substrate, one or more electrical interconnects disposed in through-substrate vias extending vertically from an upper surface of the substrate to a lower surface of the substrate, one or more optical interconnects embedded in the substrate between the upper surface of the substrate and the lower surface of the substrate, and one or more optical connector pin holes extending from at least one side of the substrate between the upper surface of the substrate and the lower surface of the substrate.

In embodiments, the substrate is a glass substrate.

In embodiments, the substrate is a silicon substrate.

In embodiments, the one or more optical interconnects include one or more rows of optical waveguide arrays.

In embodiments, at least one of the one or more rows of optical waveguide arrays extends from a first side of the substrate to a second side of the substrate. The first side of the substrate may be opposite the second side of the substrate, and the at least one of the one or more rows of optical waveguide arrays extends straight through the substrate from the first side to the second side. The first side of the substrate may alternatively be next to the second side of the substrate, and the at least one of the one or more rows of optical waveguide arrays curves through the substrate from the first side to the second side.

In embodiments, at least one of the one or more rows of optical waveguide arrays extends from a first side of the substrate to the upper surface of the substrate. The at least one of the one or more rows of optical waveguide arrays may be tapered from the first side of the substrate to a given portion of the upper surface of the substrate that is configured for attachment to a photonic die, wherein at least one of the one or more electrical interconnects contacts the given portion of the upper surface of the substrate that is configured for attachment to the photonic die.

In embodiments, the semiconductor structure further includes one or more additional electrical interconnects disposed on at least one of the upper and lower surfaces of the substrate.

According to an aspect of the invention, a co-packaged optics structure includes a substrate having one or more electrical interconnects and one or more optical interconnects, the one or more electrical interconnects extending vertically between upper and lower surfaces of the substrate, the one or more optical interconnects being embedded in the substrate between the upper and lower surfaces of the substrate, wherein at least a subset of the one or more optical interconnects extend from (i) at least one side of the substrate between the upper and lower surfaces of the substrate to (ii) a first portion of the upper surface of the substrate. The co-packaged optics structure also includes at least one photonic die coupled to the first portion of the upper surface of the substrate, and at least one electrical die coupled to a second portion of the upper surface of the substrate.

In embodiments, the substrate is a glass substrate.

In embodiments, the co-packaged optics structure further includes one or more additional electrical interconnects disposed proximate the upper surface of the substrate interconnecting the at least one photonic die and the at least one electrical die.

In embodiments, the co-packaged optics structure further includes one or more optical connector pin holes extending from at least one side of the substrate to an interior portion of the substrate between the upper and lower surfaces of the substrate.

In embodiments, at least an additional subset of the one or more optical interconnects extend from a first side of the substrate to a second side of the substrate between the upper and lower surfaces of the substrate. The additional subset of the one or more optical interconnects may be configured for coupling with one or more additional optical interconnects of one or more additional co-packaged optics structures. The second side of the substrate may be opposite the first side of the substrate.

According to an aspect of the invention, a photonics system includes a first co-packaged optics structure and a second co-packaged optics structure. The first co-packaged optics structure includes a first substrate with a first set of optical interconnects embedded between upper and lower surfaces of the first substrate. The second co-packaged optics structure includes a second substrate with a second set of optical interconnects embedded between upper and lower surfaces of the second substrate. At least a first subset of the first set of optical interconnects of the first co-packaged optics structure are coupled with at least a second subset of the second set of optical interconnects of the second co-packaged optics structure.

In embodiments, the first co-packaged optics structure further includes one or more optical connector pin holes extending from a side of the first substrate to an interior portion of the first substrate between the upper and lower surfaces of the first substrate. The photonics system may further include at least one optical connector having one or more optical connector pins coupled with the one or more optical connector pin holes of the first co-packaged optics structure.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

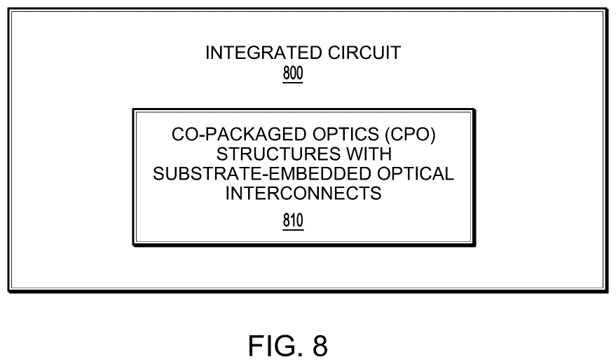

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 8 shows an example integrated circuit 800 which includes one or more co-packaged optics structures 810 with substrate-embedded optical interconnects.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. With respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a substrate;
one or more electrical interconnects disposed in through-substrate vias extending vertically from an upper surface of the substrate to a lower surface of the substrate;
one or more optical interconnects embedded in the substrate between the upper surface of the substrate and the lower surface of the substrate; and
one or more optical connector pin holes extending from at least one side of the substrate between the upper surface of the substrate and the lower surface of the substrate.

2. The semiconductor structure of claim 1, wherein the substrate is a glass substrate.

3. The semiconductor structure of claim 1, wherein the substrate is a silicon substrate.

4. The semiconductor structure of claim 1, wherein the one or more optical interconnects comprise one or more rows of optical waveguide arrays.

5. The semiconductor structure of claim 4, wherein at least one of the one or more rows of optical waveguide arrays extends from a first side of the substrate to a second side of the substrate.

6. The semiconductor structure of claim 5, wherein the first side of the substrate is opposite the second side of the substrate, and wherein said at least one of the one or more rows of optical waveguide arrays extends straight through the substrate from the first side to the second side.

7. The semiconductor structure of claim 5, wherein the first side of the substrate is next to the second side of the substrate, and wherein said at least one of the one or more rows of optical waveguide arrays curves through the substrate from the first side to the second side.

8. The semiconductor structure of claim 4, wherein at least one of the one or more rows of optical waveguide arrays extends from a first side of the substrate to the upper surface of the substrate.

9. The semiconductor structure of claim 8, wherein said at least one of the one or more rows of optical waveguide arrays are tapered from the first side of the substrate to a given portion of the upper surface of the substrate that is configured for attachment to a photonic die, wherein at least one of the one or more electrical interconnects contacts the given portion of the upper surface of the substrate that is configured for attachment to the photonic die.

10. The semiconductor structure of claim 1, further comprising one or more additional electrical interconnects disposed on at least one of the upper and lower surfaces of the substrate.

11. A co-packaged optics structure comprising:
a substrate having one or more electrical interconnects and one or more optical interconnects, the one or more electrical interconnects extending vertically between upper and lower surfaces of the substrate, the one or more optical interconnects being embedded in the substrate between the upper and lower surfaces of the substrate, wherein at least a subset of the one or more optical interconnects extend from (i) at least one side of the substrate between the upper and lower surfaces of the substrate to (ii) a first portion of the upper surface of the substrate;
at least one photonic die coupled to the first portion of the upper surface of the substrate; and
at least one electrical die coupled to a second portion of the upper surface of the substrate.

12. The co-packaged optics structure of claim 11, wherein the substrate is a glass substrate.

13. The co-packaged optics structure of claim 11, further comprising one or more additional electrical interconnects disposed proximate the upper surface of the substrate interconnecting the at least one photonic die and the at least one electrical die.

14. The co-packaged optics structure of claim 11, further comprising one or more optical connector pin holes extending from at least one side of the substrate to an interior portion of the substrate between the upper and lower surfaces of the substrate.

15. The co-packaged optics structure of claim 11, wherein at least an additional subset of the one or more optical interconnects extend from a first side of the substrate to a second side of the substrate between the upper and lower surfaces of the substrate.

16. The co-packaged optics structure of claim 15, wherein the additional subset of the one or more optical interconnects are configured for coupling with one or more additional optical interconnects of one or more additional co-packaged optics structures.

17. The co-packaged optics structure of claim 15, wherein the second side of the substrate is opposite the first side of the substrate.

18. A photonics system comprising:
a first co-packaged optics structure, the first co-packaged optics structure comprising a first substrate with a first set of optical interconnects embedded between upper and lower surfaces of the first substrate; and
a second co-packaged optics structure, the second co-packaged optics structure comprising a second substrate with a second set of optical interconnects embedded between upper and lower surfaces of the second substrate;
wherein at least a first subset of the first set of optical interconnects of the first co-packaged optics structure are coupled with at least a second subset of the second set of optical interconnects of the second co-packaged optics structure.

19. The photonics system of claim 18, wherein the first co-packaged optics structure further comprises one or more optical connector pin holes extending from a side of the first substrate to an interior portion of the first substrate between the upper and lower surfaces of the first substrate.

20. The photonics system of claim 19, further comprising at least one optical connector having one or more optical connector pins coupled with the one or more optical connector pin holes of the first co-packaged optics structure.
